(19) United States
(12) Patent Application Publication
(10) Pub. No.: US 2026/0045297 A1
(43) Pub. Date: Feb. 12, 2026

(54) STATIC RANDOM-ACCESS MEMORY WITH ARRAY LEVEL DATA PRIVACY FUNCTIONALITY

(71) Applicant: University of Southern California, Los Angeles, CA (US)

(72) Inventors: Ajey Poovannummoottil Jacob, Los Angeles, CA (US); Akhilesh Jaiswal, Los Angeles, CA (US); Shwetha Sajitha Vijayakumar, Los Angeles, CA (US); Zihan Yin, Los Angeles, CA (US)

(21) Appl. No.: 19/298,098

(22) Filed: Aug. 12, 2025

Related U.S. Application Data
(60) Provisional application No. 63/682,245, filed on Aug. 12, 2024.

(51) Int. Cl. G11C 11/419; G11C 11/418

(52) U.S. Cl. CPC G11C 11/419; G11C 11/418

(57) ABSTRACT

Provided is a memory circuit including a pair of cross-coupled inverters, the pair of cross-coupled inverters accessible by bit lines, wherein the access of the bit lines to the pair of cross-coupled inverters is controlled by access transistors, the access transistors controlled by a word line, and a dynamic node between one of the access transistors and one of the bit lines, the dynamic node storing a bit value.

### CROSS-REFERENCE TO RELATED APPLICATIONS

This patent claims the benefit of priority to U.S. Provisional Patent Application 63/682,245, filed Aug. 12, 2024, titled STATIC RANDOM-ACCESS MEMORY (SRAM) BASED ON NINE TRANSISTOR ARRANGEMENT WITH ARRAY LEVEL DATA PRIVACY FUNCTIONALITY. The entire content of each afore-listed patent-filing is hereby incorporated by reference for all purposes.

### BACKGROUND

### 1. Field

The present disclosure relates generally to the field of computer processing and more particularly to digital in-memory computing.

### 2. Description of the Related Art

As data collection becomes cheaper, with increased data collection capabilities (e.g., text, video, audio, image, etc. across multiplying devices such as phones, tablets, smart watches, security cameras, doorbells, smart speakers, etc.) and decreased data storage cost (e.g., as provided by cloud storage and due to decreased per gigabyte cost), more and more processes integrate inference and other machine learning (ML) or artificial intelligence (AI) based operations to provide intelligent computing solutions to consumers (such as facial recognition, voice identification, etc.). However, even as data storage costs decrease, security and energy efficiency concerns remain, both for data storage and processing and for the transfer of data between storage and processing, such as through the memory-wall bottleneck.

In some cases, application of computing to data while or as stored in memory (e.g., in-memory computing) may be used to perform data acceleration, performing some computing tasks in memory and thereby reducing the total amount of data (and possibly increasing security of such data) to be transmitted for further processing. While in-memory computing may be analog or digital, digital in-memory computing in static random-access memory (SRAM) may be particularly useful for integration into on-chip memory (where data values in SRAM are relatively long-lived with low power and refresh requirements but also rewritable), and as SRAM is the most widely used on-chip memory, it is therefore well characterized. For energy efficiency reasons, binary neural networks (BNN), in which weights and other values take binary values, may be selected for in-situ acceleration, where the “exclusive or” (XOR) may be a computational unit of BNNs and circuitry which performs the XOR operation may be integrated into memory. However, XOR operations can be difficult to perform within some forms of SRAM, as XOR operations may have to be applied individually to cells of SRAM, instead of batch applied over multiple rows. Additionally, SRAM may suffer from security concerns, where some forms of SRAM may be prone to data imprinting (as threshold voltage increases due to transistor aging), data remanence, etc. Data stored in such SRAM may therefore be retrieved, in some cases, including by bad actors, due to the physical architecture of the memory, and expose various parameters of in-memory computing (including possibly machine learning model parameters) to malicious discovery. None of the discussion of challenges with various approaches above or below should be read as disclaimer or disavowal of any material.

### SUMMARY

While the present techniques may be susceptible to various modifications and alternative forms, specific embodiments thereof are shown by way of example in the drawings included or described herein. The drawings may not be to-scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims. Further, the description of problems (to be solved, with other techniques, technical problems, etc.) should not be read to imply that all embodiments must fully eliminate those problems, or that any techniques suffering to some degree from such problems are disclaimed, as various inventive techniques are described and various engineering and cost trade-offs may result in only subsets of such problems being mitigated only partially by some embodiments consistent with the present techniques. The discussion of trade-offs between cell architectures, array architectures, models, or with respect to other topics herein, should not be read to imply any disavowal or disclaimer of claim scope.

The following is a non-exhaustive listing of some aspects of the present techniques. These and other aspects are described in the following disclosure.

Some aspects include a memory cell, which may be a static random-access memory (SRAM) cell.

Some aspects include a memory cell containing nine transistors in a SRAM configuration.

Some aspects include a memory cell with a first word line and a second word line.

Some aspects include a memory cell with a data line.

Some aspects include a memory cell with a pair of bit lines, including a pair of bit lines which may have inverted signals applied (e.g., a bit line and a NOT bit line).

Some aspects include a memory cell with access transistors, which may be operated by a word line, and which may control the ability of the bit lines to access the memory cell.

Some aspects include a memory cell with a reset bit line, which may provide a signal to a reset transistor.

Some aspects include a memory cell with a reset transistor, which may be controlled by a data line and provided with a signal by a reset bit line.

Some aspects include memory cell with a data storage node, which may store a dynamic value of the bit cell.

Some aspects include a memory cell with cross-coupled inverters.

Some aspects include a memory cell with cross-coupled inverters composed of four transistors.

Some aspects include a memory cell which is volatile memory.

Some aspects include a memory cell which is nonvolatile memory, such as nonvolatile SRAM (nvSRAM).

Some aspects include an array of memory elements.

Some aspects include an array of memory elements, where at least some of the memory elements may be operational compared with operands by applying signals to the memory elements.

Some aspects include an array of memory elements, where at least some of the bit values of the memory elements may be compared by XOR with operands.

Some aspects include an array of memory elements, where at least some of the bit values of the memory elements may be compared by XOR with the same operand in substantially the same operation.

Some aspects include an array of memory elements, where the bit values of a row of memory elements may be compared by XOR with the same or a different operand in substantially the same operation.

Some aspects include an array of memory elements, where the bit values of multiple rows of memory elements may be compared by XOR with the same or a different operand in substantially the same operation.

Some aspects include an array of memory elements, where bit values of at least some of the memory elements may be conditionally flipped (e.g., toggled) by application of a signal.

Some aspects include an array of memory elements, where bit values of at least some of the memory may be reset by application of a signal.

Some aspects include an array of memory elements, where bit values of at least some of the memory elements may be erased by application of a signal.

Some aspects include an array of memory elements, where the array performs at least some operations of a neural network (NN) through in-memory computing.

Some aspects include an array of memory elements, where the array performs at least some operations of a binary neural network (BNN) though in-memory computing.

Some aspects include additional processing circuitry in the array of memory elements.

Some aspects include a method of fabricating one or more memory element or an array thereof.

Some aspects include a method of performing an XOR operation using bit values of a memory cell or array thereof.

Some aspects include a method of performing a parallel XOR operation using bit values of a memory cell or array thereof.

Some aspects include a method of performing a massively parallel XOR operation using bit values of a memory cell or array thereof.

Some aspects include a method of performing conditional flipping of bit values of a memory cell or array thereof.

Some aspects include a method of performing erasing of bit values of a memory cell or array thereof.

Some aspects include a method of performing resetting of bit values of a memory cell or array thereof.

While the techniques described herein may be implemented in various forms, specific embodiments are illustrated by way of example in the drawings included or described. The drawings may not be to scale. It should be understood that the drawings and detailed descriptions are not intended to limit the scope of the techniques to the specific forms disclosed. Rather, the intention is to encompass all modifications, equivalents, and alternatives consistent with the appended claims. In addition, any discussion of technical problems or shortcomings associated with existing approaches should not be interpreted to imply that all embodiments eliminate such problems entirely, or that any particular technique suffering from such issues is disclaimed. Some embodiments may address only subsets of such problems or reflect trade-offs based on engineering or design constraints. Similarly, any discussion of trade-offs between cell or array architectures, computational models, or system-level considerations should not be viewed as limiting claim scope.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 depicts an example nine transistor (9T) SRAM cell, in accordance with one or more embodiments;

FIG. 2 depicts example operation of an array of 9T SRAM cells in an XOR operation, in accordance with one or more embodiments;

FIGS. 3A-3B depict simulated behavior of a 9T SRAM cell during XOR operations, in accordance with one or more embodiments;

FIG. 4 is a block diagram illustrating a write operation of a 9T SRAM cell, in accordance with one or more embodiments;

FIG. 5 is a block diagram illustrating a read operation of a 9T SRAM cell, in accordance with one or more embodiments; and

FIG. 6 depicts an example computing system in which one or more of the above-noted embodiments may be used.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of static random-access memory architectures and logic-in-memory integration. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

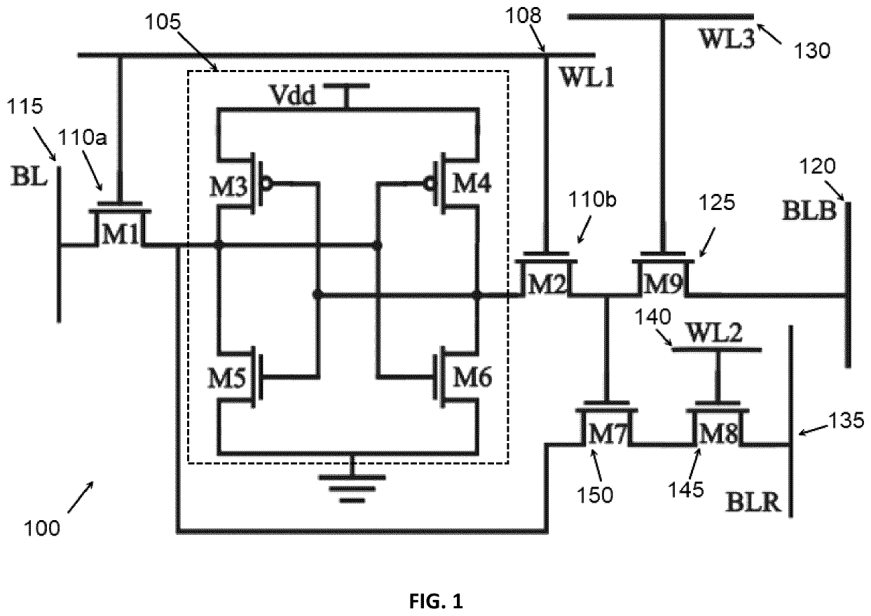

FIG. 1 depicts an example 9T SRAM cell 100, which includes a pair of cross-coupled inverters 105 configured to store a bit value. Other embodiments may have more transistors or fewer. The pair of cross-coupled inverters 105 may be accessible via two bit lines: a first bit line 115 (BL) and a second bit line 120 (BLB). In some embodiments, the SRAM cell is made with A first access transistor 110a (M1) may be coupled in series (e.g., with a source, drain, and channel in series) between the first bit line 115 and a first storage node of the cross-coupled inverters 105, e.g., to a right inverter in the image. A second access transistor 110b (M2) may be coupled in series (e.g., with a source, drain, and channel in series) between the second bit line 120 and a second storage node of the cross-coupled inverters 105, e.g., to a left inverter in the image. Both the first and second access transistors 110a and 110b may be controlled by (e.g., have a gate electrically coupled to) a first word line 108 (WL1), which when asserted (like when in a state that causes transistors 110a and 110b to have a conductive channel) in some embodiments allows for read and write access to the memory cell through the bit lines in some embodiments. (In some embodiments, pMOS and nMOS devices may be swapped, and voltages that constitute assertion may be reversed.) A dynamic node may be interposed in series (e.g., with a source, drain, and channel in series) between a source or drain of the second access transistor 110b and the second bit line 120. A third transistor 125 (M9) may be also interposed between the dynamic node and the second bit line 120, forming a gated conduction path that may be selectively rendered conductive, depending on the voltage applied to the gate of transistor 125. The third transistor 125 may be controlled by a third word line 130 (WL3). When activated, the third transistor 125 may allow a signal from the second bit line 120 to propagate to the dynamic node and, depending on the state of the second access transistor 110b, into the cross-coupled inverters 105.

Connected to the dynamic node, in some embodiments, is a first reset transistor 150 (M7). The gate terminal of the first reset transistor 150 may be coupled to the dynamic node, and its conduction path may extend from the dynamic node to a region between the first access transistor 110a and the corresponding node of the cross-coupled inverters 105. This reset path, in some embodiments, forms part of a feedback-driven control structure that conditionally modifies the state of the stored bit. The first reset transistor 150 may be further connected to a second reset transistor 145 (M8), which is coupled to a reset bit line 135 (BLR). The second reset transistor 145 is controlled by a second word line 140 (WL2). When activated, in some embodiments, the second reset transistor 145 permits propagation of a signal from the reset bit line 135 to be applied to the first reset transistor 150, which, if also activated by the dynamic node, causes the stored value in the cross-coupled inverters 105 to be reset or toggled based on the logic level on the reset bit line 135.

In some embodiments, the 9T SRAM cell includes internal storage nodes Vx and Vy, which correspond to the output nodes of the pair of cross-coupled inverters. Vx may be located at the junction between the first inverter and the first access transistor 110a, while Vy may be located at the junction between the second inverter and the second access transistor 110b. These nodes may define the bistable state of the memory cell and collectively store a single bit of data, with Vx and Vy typically holding complementary logic levels (e.g., binary storage of a single bit of information per SRAM cell 100).

In some embodiments, the 9T SRAM cell may facilitate SRAM operation in both read/write modes and logic or security-oriented modes, such as in-memory XOR computation, secure data erase, and state-aware toggling. The dynamic node may function as an operand-sensitive staging point that permits conditional gating of the reset path based on operand data or internal state. The use of multiple word lines and a reset bit line may provide flexible access control and signal routing and may facilitate logic-level manipulation directly within the memory cell. The cell 100 may include 6T SRAM elements (transistors M1-M6) and additional transistors M7, M8 and M9 for supporting XOR operations and flipping the value stored in the bit-cell, which, as described below, may be used for multi-row XOR and massively parallel data-toggling operations. In some embodiments, the collective 9T SRAM cell 100 can work in SRAM read and write mode as well as in massively parallel array-level XOR operation mode.

Some embodiments may include an array, like a 2D array, with rows and columns of SRAM cells like cell 100, e.g., with cells in the same row sharing word lines and cells in the same column sharing bit lines.

In some embodiments, each column of the 9T SRAM array includes a dedicated data line (DL) that may be electrically coupled to the gate terminal of a transistor within the reset logic path. The data line may be used to apply a logic-level control signal that corresponds to operand B, for instance during conditional reset or logic operations such as in-memory XOR or erase modes. The DL signal may originate from a register file or logic controller located at the periphery of the array and may be shared across multiple rows within a given column. In some embodiments, during a logic-enabled operation, such as data toggling or conditional bit flipping, the DL line may be pulled to a logic high level when operand B is equal to logic “1.” This may turn ON the transistor to which it is tied when its associated word line is also asserted, allowing the reset bit line to charge a dynamic node located within the bitcell. If operand B is logic “0,” the DL may remain at ground potential, keeping the tied transistor OFF and thereby preventing signal propagation into the reset path. In some embodiments, the DL line may be pulsed concurrently with or just prior to the activation of the third word line 130, such that the dynamic node is charged to a voltage corresponding to operand B before additional logic transistors are evaluated. The DL signal may be held static during the duration of the operation or may be briefly pulsed, depending on timing and/or drive strength constraints.

In some embodiments, the transistors along the reset path may be dimensioned to exhibit higher on-current characteristics than other transistors in the memory cell. In some embodiments, the electrical performance of the transistors along the reset path may be enhanced by increasing their channel width-to-length (W/L) ratio. A larger W/L ratio may increase the available channel width, which may raise the on-state drive current when the transistor is enabled. In some embodiments, a larger W/L ratio may facilitate rapid discharge of the storage node Vx, particularly during conditional reset or erase operations. The W/L ratio may be adjusted non-uniformly across transistors in the series reset path to account for voltage drop, parasitic resistance, or stage-specific delay sensitivity. In some embodiments, the reset path transistors may be implemented using low-threshold voltage devices. Lowering the threshold voltage may allow these transistors to switch on at reduced gate voltages, improving their responsiveness in conditions where signal levels are degraded or limited, for example, during low-voltage operation, near-threshold computing, or in the presence of transistor aging.

In some embodiments, the transistors along the reset path may be implemented using dual-gate, FinFET, or fully depleted silicon-on-insulator (FDSOI) devices. FinFET devices may include multiple fins to increase drive strength without increasing planar footprint, while FDSOI devices may leverage back-gate biasing to dynamically adjust the effective threshold voltage during operation. In dual-gate configurations, the additional gate terminal may be used to reinforce conduction or suppress leakage depending on the operating mode. These transistor architectures may offer improved electrostatic control, reduced variability, and increased current density, over some alternate approaches, thereby improving the robustness and responsiveness of the logic-controlled erase path.

In some embodiments, transistors 145 and 150 may be configured with sizing ratios at least 1.5× larger than the access transistors 110a and 110b, or the minimum width transistors forming the pair of cross-coupled inverters 105. These ratios may be tuned based on fabrication process parameters, target switching speed, or the desired noise margin during reset events. The increased drive strength may help overcome leakage, capacitive charge retention, or variability in the SRAM cell, particularly under reduced supply voltage or aged device conditions.

In some embodiments, the erase path may include dynamic control logic to adjust the timing or magnitude of the reset signal applied to the reset bit line 135, depending on the logic state of the dynamic node or previously stored data. For example, adaptive erase drivers may ramp BLR voltage based on sensed impedance or cell temperature. In some embodiments, the first reset transistor 150 may be implemented using a transistor with enhanced gate overdrive capability, such as a back-bias-enabled FDSOI or body-tied FinFET, to improve switching performance under low-voltage or high-leakage conditions.

In some embodiments, the 9T SRAM cell may operate in a normal mode configuration that supports SRAM read and write operations. In this mode, the cell may operate using a pair of bit lines and one or more word lines to access and modify a stored bit value through controlled conduction paths within the cell. During read/write operation, the logic signal input line and reset path transistors associated with in-memory logic (e.g., transistors 145 and 150) may be disabled, and the reset bit line 135 may be held inactive. This may allow the central storage and access paths to operate independently of the remaining circuitry.

In some embodiments, the 9T SRAM cell may be configured for write operations in a normal mode configuration. In some embodiments, both the first word line 108 (WL1) and the third word line 130 (WL3) are asserted high to write a bit value into the 9T SRAM cell. The first word line 108 may be asserted high to enable the standard access transistors 110a and 110b, which are coupled between the respective bit lines 115 and 120 and the cross-coupled inverters 105. The third word line, when asserted, may activate the third access transistor 125, which may be configured to lie in series with the second access transistor 110b and may be interposed between the second bit line 120 and the cross-coupled inverter node associated with the second access transistor 110b.

To store a logical “1,” for example, bit line 115 may be driven high (VDD) and bit line 120 may be driven low (GND). The conduction paths formed through the first and second access transistors 110a and 110b and the third transistor 125 may allow the differential voltage to overwrite the existing state of the cross-coupled inverters. Depending on the data pattern, either node Vx or Vy may be charged or discharged accordingly, thereby flipping the bistable inverter latch into the desired state. This operation may proceed without involvement of the reset or dynamic logic paths.

In some embodiments, the 9T SRAM cell may be configured for read operations in a normal mode configuration. In some embodiments, the bit lines 115 and 120 may be precharged to a known voltage level, typically VDD to perform a read operation. The first and third word lines 108 and 130 may again be asserted to enable the access transistors. The stored bit value may differentially discharge one of the bit lines via the conduction path from Vx through the first access transistor 110a or from Vy through the second access transistor 110b and the third transistor 125, depending on which node stores logic “0.” In some embodiments, a differential sense amplifier may be connected at the column periphery to detect the resulting voltage differential between the first and second bit lines and resolve the stored logic level.

In some embodiments, the 9T SRAM architecture may be deployed across multiple physical tiers using monolithic three-dimensional integration or heterogeneously integrated stacking, depending on fabrication constraints and system-level design requirements. In some embodiments, multiple device layers (such as logic, memory, or pass-gate control circuits) may be fabricated sequentially on a single wafer with low-temperature back-end-of-line processing used to form upper-layer transistors. In some embodiments, oxide-based thin-film transistors, carbon nanotube FETs, or indium-gallium-zinc oxide (IGZO) devices may be deposited over a silicon CMOS base layer without exceeding thermal budgets that could disturb previously-formed junctions. In some embodiments, the cell 100 is made with CMOS (complementary metal oxide semiconductor) technology, e.g., on a monolithic semiconductor substrate, like in a packaged chip.

In some embodiments, the SRAM storage elements may reside on one layer, while operand routing, control logic, or security-specific functionality may be placed on a separate tier, directly above or below the memory array. Vertical vias or through-layer interconnects may couple logic outputs to word lines, bit lines, or reset paths across the tiers. Some embodiments may reduce interconnect length between memory and associated compute or control circuitry, potentially improving energy efficiency and timing performance. Such embodiments may allow localized distribution of operand B values or reset triggers per column without routing congestion at the array periphery.

In some embodiments, the 9T memory architecture may be implemented independently of any particular underlying transistor or process technology, and may be realized using a wide variety of fabrication platforms. In some embodiments, the cell structure may be instantiated in planar bulk CMOS, fully depleted silicon-on-insulator (FDSOI), FinFET, or gate-all-around (GAA) technologies at different process nodes. In some configurations, the relative sizing and threshold voltages of the access and reset transistors may be adjusted according to device geometry and supply voltage constraints.

In some embodiments, the 9T SRAM cell may be implemented using non-silicon materials or alternative channel technologies (such as amorphous oxide semiconductors, 2D materials, or monolayer semiconductors) such as in configurations where the reset or logic path transistors are fabricated in a different tier than the main inverter latch. These upper-tier devices may serve as gating or signal conditioning elements without requiring high mobility or low-threshold operation.

In some embodiments, the disclosed 9T SRAM cell and associated memory architectures may be realized using heterogeneously integrated stacking techniques. Such integration may utilize approaches including through-silicon vias (TSVs), micro-bumps, wafer-level bonding, or die-to-wafer bonding, allowing separately optimized semiconductor technologies to coexist within the same integrated package or chip stack. In some embodiments, the described 9T SRAM cell array may reside on one semiconductor die, fabricated using a high-density CMOS process optimized specifically for SRAM performance and density. Adjacent logic or processing functions (such as security co-processors, operand routing logic, control and timing circuitry, or neural processing units) may be fabricated on separate dies using distinct technologies. These dies may then be stacked vertically and interconnected through TSVs or interposer layers, which provide short, high-bandwidth, and low-latency inter-chip connections.

In some embodiments, heterogeneous integration may involve combining memory-specific optimized layers (such as DRAM, RRAM, or MRAM technologies) with the 9T SRAM logic-in-memory structure. In some embodiments, a hybrid memory stack may include a DRAM die positioned above or below a 9T SRAM die, with vertical interconnections enabling direct memory-to-memory operations, logic-assisted memory access, or secure erase functionality. This arrangement may be advantageous for applications requiring large memory densities alongside secure or logic-intensive operations, such as secure boot processors, edge inference accelerators, or cryptographic engines.

In some embodiments, the disclosed 9T SRAM architecture may be integrated within edge computing systems, such as embedded microcontrollers and IoT devices. In some embodiments, the 9T memory architecture may be employed to securely store critical data such as encryption keys, configuration parameters, or secure boot information. By incorporating operand-controlled reset and erase functionalities, some embodiments may achieve enhanced hardware-level security, reducing vulnerabilities related to data imprinting attacks, side-channel leakage, or persistent memory artifacts.

In some embodiments, the disclosed 9T SRAM architecture may be configured for integration within artificial intelligence (AI) accelerator hardware, such as systems designed for embedded and edge computing environments. Such AI accelerators may include neural processing units (NPUs), tensor processing units (TPUs), vision processing modules, inference engines, and hardware accelerators deployed in robotics, autonomous vehicles, IoT devices, devices with systolic arrays, and the like. Some embodiments may leverage massively parallel XOR operations directly within the memory array to perform ML tasks such as BNN inference, convolutional operations, and binary-weighted matrix multiplications. Some embodiments may benefit real-time inference tasks such as voice recognition, image classification, facial detection, or keyword spotting, which are widely deployed in mobile, automotive, or IoT platforms. In some embodiments, the disclosed memory cells may be implemented in security-focused hardware, such as secure processing units, trusted platform modules or cryptographic co-processors. The conditional reset and data toggling functionality described herein may provide intrinsic hardware-based protection against data remanence and threshold voltage shifts, making it suitable for secure computation environments where sensitive data must be securely erased or regularly refreshed at the transistor level.

In some embodiments, the described architecture may be integrated into multi-tiered or heterogeneously stacked system-on-chip platforms, where different semiconductor technologies (including high-performance logic, nonvolatile memory, DRAM, or emerging memory devices) may be stacked vertically using interposers or chiplet-based packaging. Some embodiments may utilize heterogeneous integration methods to leverage the SRAM cell's logic-aware structure to perform conditional memory resets, secure memory erasure, or logic operations directly at the memory plane, substantially improving system-wide energy efficiency, reducing latency, and enhancing security at the memory subsystem level. In some embodiments, the described memory structure may be integrated within computing architectures that prioritize low-power, energy-efficient operation, such as wearable devices, battery-operated sensors, or implanted medical devices. In some embodiments, the low-overhead logic-in-memory capabilities provided by the 9T SRAM architecture may support enhanced functionality (such as secure data erasure, periodic toggling to mitigate aging effects, or direct binary computation) without imposing significant additional power or area overheads. Consequently, these embodiments may enhance both the security and operational longevity of highly constrained embedded devices.

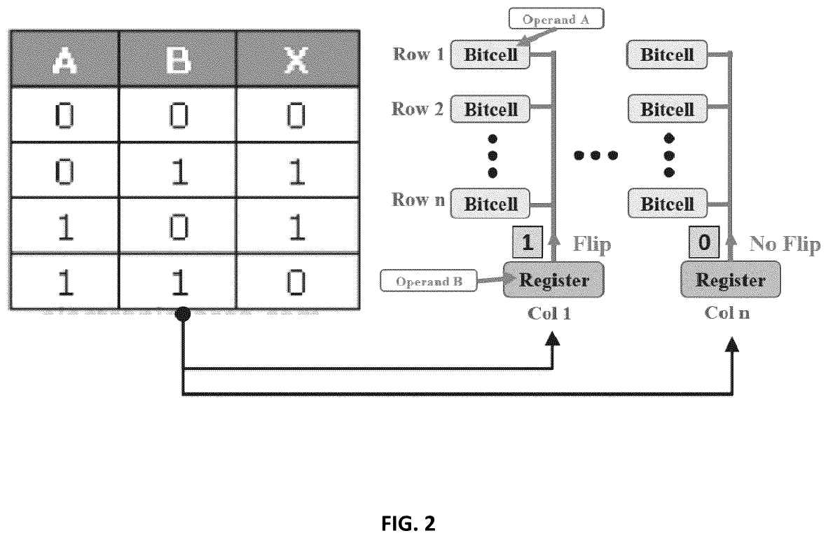

FIG. 2 depicts example operation of a memory array comprising multiple 9T SRAM cells, such as the cell depicted in FIG. 1. In some embodiments, the 9T SRAM cells may be arranged in rows and columns, where each column shares a common set of vertical control and data lines, including a bit line 115, complementary bit line 120, and a reset bit line 135. Each row may be associated with horizontal word lines, including a first word line 108, a second word line 140, and a third word line 130, which selectively control access and logic transistors within each cell. Each individual cell may include a pair of cross-coupled inverters configured to store a bit value (operand A), along with access and logic transistors configured to support in-memory exclusive-OR (XOR) operations.

In one or more embodiments, a second operand (operand B) may be applied to the memory array as a control signal for initiating conditional logic within the cells. Operand B may be stored in or propagated from a register bank positioned at the periphery of the array, such as one register per column. Each register may drive a column-specific logic signal line which may be routed vertically to all cells in the corresponding column. Operand B may be represented as a logic level (e.g., VDD for logic “1” or GND for logic “0”) and selectively applied to the reset bit line 135 in each column. In some embodiments, the reset bit line 135 may be electrically coupled to a sequence of logic transistors which form a conduction path through which the reset bit line 135 signal can reach one of the storage nodes of the cross-coupled inverters depending on gating conditions.

In some embodiments, each 9T SRAM cell of an array may include a dynamic logic path responsive to operand B. In some embodiments, when operand B is high (e.g., a logic “1”), the signal may be applied to the reset bit line 135 and gated through a second reset transistor 145, which may be activated by the second word line 140. The signal may then be staged at a dynamic node, which in turn serves as the gate for the first reset transistor 150. If the dynamic node charges to logic “1,” the first reset transistor 150 may turn ON, therefore propagating the signal through a third transistor 125, which may be controlled by the third word line 130. This chain of conduction, from the reset bit line 135 to the second reset transistor 145 to the first reset transistor 150 to the third transistor 125, may terminate at a storage node of the latch, allowing that node to be discharged (e.g., via a negative BLR pulse or logic-low level), thereby flipping the bit stored in the cell. This may result in the stored bit A being overwritten with A⊕B.

In some embodiments, when operand B is logic “0,” the reset bit line 135 may remain at GND, and the dynamic node may fail to reach the threshold required to turn on the first reset transistor 150. In that case, the reset path may remain blocked, and no change is applied to the latch. As such, the logic operation may be conditional: the bit value is flipped when operand B is high. The process may not require an external read, decode, or writeback and may be executed within the cell's internal circuitry.

In some embodiments, the XOR-based logic path may support scalable, fine-grained control of logic operations at the cell level while also supporting simultaneous broadcast of operand B values across multiple cells. Because the reset bit line 135 and word lines (WL2 140 and WL3 130) may be shared among rows and columns, the same operand B may be concurrently applied to all cells in a column. When the first word line 108 is asserted across multiple rows, and corresponding the second word line 140 and the third word line 130 lines are active, each row may perform the XOR operation in parallel using its own operand A value and the shared operand B.

In some embodiments supporting a maximally parallel configuration, each bitcell in a memory array may simultaneously or concurrently perform a one-bit XOR computation, thereby facilitating massively parallel, array-level in-memory logic. This may be particularly advantageous in applications such as BNNs, where operands representing input activations (operand B) must be XORed against stored weights (operand A) across many rows of memory in a single compute cycle.

In some embodiments, the XOR operation may be implemented within each 9T SRAM cell by activating a series of transistors that form a conditional logic path. This path may include a first reset transistor 150 controlled by the dynamic node, a second reset transistor 145 controlled by a second word line 140, and an intermediate logic transistor gated by a dynamic node. The operand B value may be applied to a reset bit line that is common to all cells within a column. When WL2 is asserted, the reset bit line may be coupled to a dynamic node within each selected cell via the first reset transistor. The voltage at this dynamic node may reflect the logic level of operand B. If operand B is a logic high, the dynamic node may charge to a level sufficient to activate the intermediate logic transistor. The intermediate logic transistor, in turn, may gate a signal from BLR to one of the storage nodes (e.g., node Vx) of the cross-coupled inverters when WL3 is asserted. If operand B is a logic low, the dynamic node may remain low, therefore preventing activation of the logic transistor, and no XOR action is performed.

In some embodiments, XOR operation may involve coordinated activation of at least three word lines. WL1 may be asserted across all rows selected for XOR processing and enable the standard access transistors, allowing the cell to transition into logic-evaluation mode. WL2 may be pulsed to facilitate propagation of the operand B signal from BLR to the dynamic node, and WL3may be subsequently asserted to conditionally propagate the signal from the dynamic node to the storage node of the latch via the second reset transistor. In some embodiments, WL2 and WL3 may be activated sequentially or in overlapping fashion depending on timing constraints and desired cell behavior. The sequence may be designed such that the dynamic node is evaluated before the logic path becomes conductive, thereby reducing the likelihood of unintended flipping of the stored bit.

In some embodiments, during XOR operations, the primary bit lines (BL and BLB) used in SRAM read and write operations may be disabled or left floating. In some embodiments, these bit lines may be precharged and then held at a fixed voltage level (e.g., VDD or GND) to avoid signal contention or current leakage. The XOR logic path may instead be driven by the reset bit line, which is the sole source of logic input into the cell during operand-controlled operations. This isolation may confine logic processing to the internal circuitry of each cell, allowing read and write paths to remain unaffected during in-memory compute operations.

In some embodiments when operand B is a logic zero, the signal applied to BLR may remain at or near ground potential. As a result, the dynamic node may fail to charge to a sufficient level to activate the intermediate logic transistor. Consequently, even if WL3 is subsequently asserted, the path from BLR to the latch node may remain blocked. In some embodiments, the value stored in the cross-coupled inverters may be preserved, and no bit flipping occurs. This conditional gating mechanism may facilitate selective bit flipping based on operand B and supports vector-wise application of logic operations across the array.

In some embodiments, the operand B values used for XOR operations may be stored in a set of column-wise registers located at the bottom or other part of a periphery of the memory array. In some embodiments, each register may be coupled to a corresponding BLR line and is capable of storing a one-bit operand B value that is broadcast upward to all cells in the associated column. Some embodiments may support per-column control of operand B, allowing a vector operand B to be applied simultaneously across the full width of the array. Each row, in turn, may perform a bitwise XOR between its stored data and the operand B value of its column, in some embodiments. This configuration may support massively parallel execution (e.g., concurrently XORing more than 64, more than 128, more than 256, more than 512, or more than 1024 pairs of values in memory), as each cell in the array may be updated in a single cycle based on a full-row activation of WL1, followed by synchronized assertion of WL2 and WL3.

In some embodiments, the described XOR operation may be initiated through internal signal propagation paths and may not require external sensing or readout of the stored bit value prior to logic execution. Operand B, when applied to the reset bit line, may cause the conditional logic transistors within each cell to evaluate and, if appropriate, overwrite the stored bit. The absence of off-cell data movement may eliminate energy overhead associated with some memory-logic interfaces. Additionally, this architectural structure may be extended to support other operations such as data toggling (by setting all operand B values to logic “1”) and array-wide data reset (by forcing all Vx nodes to logic “0” via controlled BLR pulses), all within the same cell design.

In some embodiments, the 9T SRAM array may be configured to support a data toggling mode, wherein each bit stored in the array is inverted concurrently across multiple rows and columns in a single cycle. This operation may be achieved by configuring the array to perform a column-wise XOR using a uniform operand B value of logic “1.” Operand B may be stored in or supplied through a dedicated register file coupled to the reset bit line 135 of each column. Each reset bit line 135 may be shared by all 9T SRAM cells within its corresponding column, and when driven high (e.g., VDD or other logic-high level), it may serve as the logic operand input for the XOR operation.

In some embodiments, the memory array may support a data toggling mode in which all stored bit values are inverted simultaneously or concurrently in a single cycle. This mode may leverage the in-memory XOR capability of the 9T SRAM cell by applying a logic “1” as operand B to all columns of the array. Operand B may be broadcast from a column-wise register file or peripheral controller via the reset bit lines (BLR). When each cell receives operand B=1, the XOR operation between the stored bit (operand A) and logic “1” may result in the complement of the original bit value.

In some embodiments, the data toggling operation may follow the same two-step process used for XOR functionality. A conditional reset may be triggered based on the operand B input. If conditions are met, a conditional bit flip may be executed. In some embodiments, each bitcell may be configured to carry out this operation independently through its internal logic circuitry. In such embodiments, when operand B is uniformly set to logic “1” across the array, the result may be a simultaneous or concurrent, bitwise inversion of all stored values. This operation may be executed frequently and with minimal overhead, facilitating dynamic redistribution of data states to reduce the likelihood of pattern-induced degradation. In some embodiments, repeated toggling may assist in counteracting data imprinting and minimize asymmetric aging effects such as negative bias temperature instability (NBTI).

In some embodiments, the 9T SRAM cell may be configured to perform an erase operation that allows forced resetting of stored bit values across an array of memory cells. In some embodiment, the erase operation may be initiated by applying a logic high signal to a reset bit line 135, which may be shared across a column of SRAM cells. The logic high signal may function as the input for an internal overwrite path. When the erase signal is present on reset bit line 135 and when control signals are applied to the third word line 130 and the second word line 140 to allow for internal signal propagation, a conduction path may be formed through a series of transistors internal to each bitcell.

In some embodiments, the second word line 140 may enable a second reset transistor 145, which may be interposed between reset bit line 135 and a first reset transistor 150. The first reset transistor 150 may be configured to have its gate terminal coupled to the dynamic node, which in turn may receive its value during prior access via conduction from the second bit line 120 through access transistor 110b and third access transistor 125, both of which may be activated by the first word line 108 and third word line 130, respectively. In some embodiments, when the dynamic node charges to a sufficient voltage level, it may activate the first reset transistor 150, completing a path from reset bit line 135, through transistors 145 and 150, to node Vx, one of the storage nodes of the cross-coupled inverters 105. As a result, node Vx may be forcibly discharged toward ground, while node Vy may be simultaneously driven to logic high through inverter feedback, thereby setting the bitcell to a known reset state. In some embodiments, this operation may occur without requiring any signal on the bit lines 115 or 120. In some embodiments, the signal may not rely on differential sensing or standard writeback operations.

Because the erase operation may be governed by internal conduction through reset-specific transistors, it may offer more deterministic and complete bit clearing than conventional access paths. In some embodiments, the erase signal on reset bit line 135 may be broadcast to all columns of a bitcell array or subarray, facilitating parallel erasure of multiple bitcells when coordinated with row-wise assertion of control signals on word lines 130 and 140. This structure may support fast, low-overhead hardware-based data sanitization and may help suppress data remanence by eliminating residual charge or bias asymmetries at the transistor level.

In some embodiments, the timing relationship between the first word line 108, the third word line 130, and the second word line 140 may influence the electrical behavior of the 9T SRAM cell during logic-based operations such as XOR, data toggling, or erase modes. In some embodiments, the first word line 108 may be asserted first to activate access transistors 110a and 110b, allowing internal nodes Vx and Vy to be coupled to bit lines 115 and 120 or to intermediate dynamic nodes. The first word line 108 may then be deasserted before subsequent word lines are activated, isolating the latch and preserving internal node conditions during logic evaluation. In some embodiments, the second word line 140 may be pulsed after the first word line 108 is deasserted to create a conduction path from the reset bit line 135 to the dynamic node via transistor 145. The timing of the second word line 140 may be selected to allow the dynamic node to charge to a voltage corresponding to operand B as carried by a data line. The third word line 130 may then be asserted to activate the first reset transistor 150, which may complete a conduction path from BLR to the storage node Vx, thereby modifying the stored bit depending on operand B and the internal state of the cell.

In some embodiments, the first word line 108 and the second word line 140 may be asserted simultaneously or concurrently, such as when initialization or internal node alignment may be desired. In some embodiments, the second and third word lines may be activated in overlapping fashion to reduce delay or simplify timing control. In some embodiments, the third word line 130 may precede the second word line 140 to precharge or condition downstream transistors prior to operand evaluation. The timing of each word line may be static, pulsed, or held over multiple cycles, and may vary based on voltage scaling, performance targets, or design constraints.

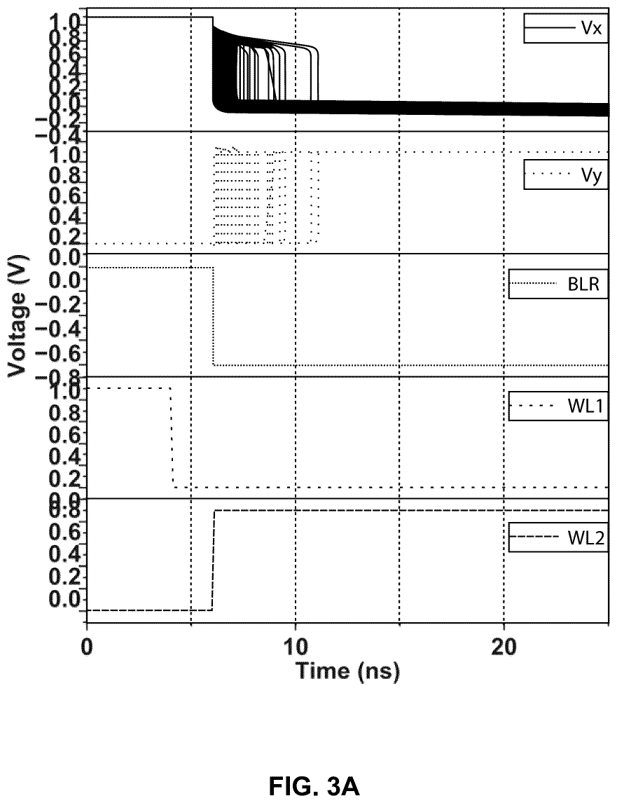

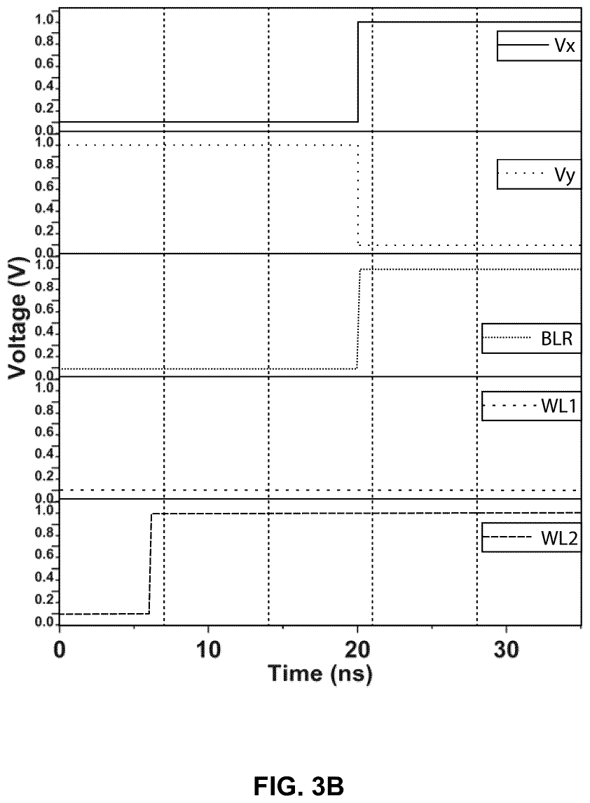

FIG. 3A illustrates example simulation results for a logic-controlled reset operation within a described embodiment of a 9T SRAM cell (like cell 100), such as may occur during a conditional overwrite or erase cycle. The waveforms shown include voltages at internal storage nodes Vx and Vy, the reset bit line 135, and word lines WL1 and WL2, plotted over a simulation time interval of 0 to 25 nanoseconds. In some embodiments, the bit line BLB may be left electrically floating, while the reset bit line 135 may be held at approximately −0.7 volts. The cross-coupled inverter pair, which includes transistors such as M3, M4, M5, and M6, may be supplied with a voltage (Vdd) of 0.9 volts. Some embodiments may obtain similar simulation results by using a Monte Carlo method across 1000 samples to reflect statistical variation for a 22-nanometer process technology. As shown in FIG. 3A, during the reset cycle, the voltage at node Vx may transition from a logic high to a logic low, while node Vy may transition from low to high, thereby setting the SRAM cell to a defined logic state. The word line WL1 may be deasserted (transitioning from high to low), while WL2 may be asserted (transitioning from low to high) during this period. The simulation results indicate that the described cell structure and control sequence may support reliable bit-level reset operations under expected process variation and operating conditions.

FIG. 3B illustrates simulation results for a logic-controlled bit-flip operation in a described embodiment of a 9T SRAM cell (like cell 100), such as may occur during the second stage of a conditional logic sequence. In this modeled scenario, voltage values for nodes Vx and Vy, reset bit line 135, and word lines WL1 and WL2 are plotted over a 35-nanosecond window. The simulation environment may mirror that of FIG. 3A, with the supply voltage (Vdd) set to 0.9 volts, BLB left floating, and BLR initially held at −0.7 volts. As with the reset simulation, 1000 Monte Carlo iterations may be executed to assess robustness under manufacturing variability in a 22-nanometer process. In some embodiments, node Vx may transition from a logic low to a logic high, while node Vy may transition from high to low, reflecting a successful in-cell inversion of the stored bit. The voltage on BLR may rise concurrently with the transition at Vx and Vy, indicating its active role in driving the state change. WL1 may remain in its previous state (e.g., high or low), while WL2 transitions from low to high to activate the gating transistors responsible for propagating operand B logic to the internal storage nodes. These simulation results demonstrate that a flip operation may be performed reliably within the timing and voltage constraints of advanced CMOS technologies, using the internal reset logic path of the 9T SRAM cell.

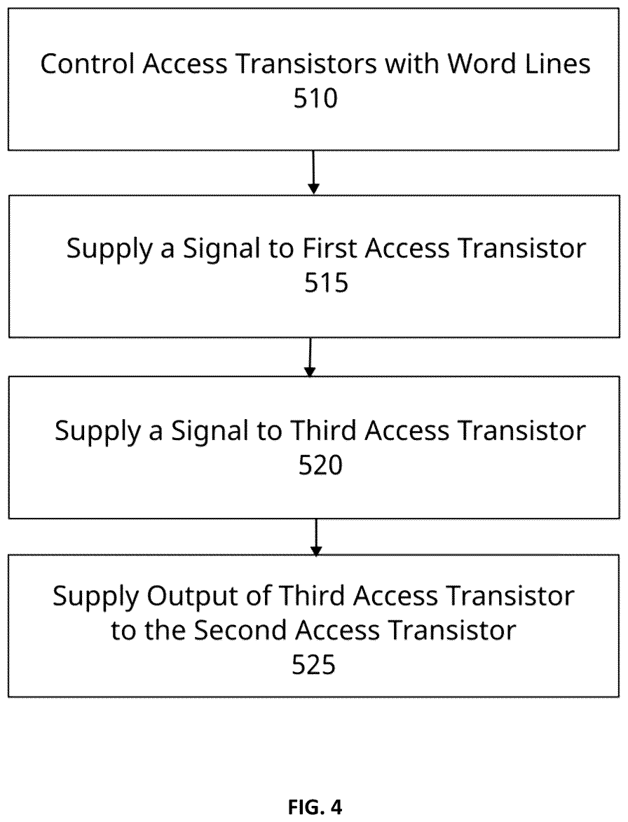

FIG. 4 is a block diagram illustrating a method for writing a bit value to a memory circuit including a 9T SRAM cell (like cell 100), in accordance with one or more embodiments. At step 510, one or more access transistors may be controlled by asserting a first word line. In some embodiments, the first word line may correspond to word line 108, which simultaneously or concurrently activates a first access transistor 110a and a second access transistor 110b. These transistors may respectively couple a first bit line 115 to one side of the cross-coupled inverter pair (e.g., node Vx), and a second bit line 120 to a dynamic node that precedes the inverter node Vy.

In some embodiments, controlling a transistor may refer to the application of a voltage signal to the gate terminal of the transistor to transition it from a non-conductive (OFF) state to a conductive (ON) state, thereby allowing current to flow between the source and drain terminals of the transistor. For example, controlling an access transistor with a word line may involve asserting the word line to a logic high voltage, sufficient to exceed the threshold voltage of the transistor, which in turn allows a signal on the corresponding bit line to be coupled to a storage node or intermediate node within the memory cell. In some embodiments, controlling may include continuous activation, pulsed gating, or time-staggered transitions depending on the desired operation and timing constraints of the memory cycle.

At step 515, a signal corresponding to the desired bit value may be supplied to the first access transistor 110a via the first bit line 115. This signal may be a logic high or logic low, depending on whether a binary “1” or “0” is to be written into the memory cell. Concurrently, a complementary signal may be applied to the second bit line 120 for differential write operations.

At step 520, a third access transistor (such as transistor 125) may be controlled by asserting a third word line (e.g., word line 130). This transistor may be interposed between the dynamic node and the second bit line 120, and its activation allows the second signal on bit line 120 to propagate toward the cross-coupled inverter node Vy.

At step 525, the output of the third access transistor 125 may be supplied to the second access transistor 110b, which then delivers the signal to the storage node Vy. The combined operation of transistors 125 and 110b may form a staged access path between the second bit line and the storage node. This configuration may support symmetric or asymmetric writing of the bit value depending on the state of the bit lines and the timing of word line activation.

The sequence of operations illustrated in FIG. 4 may be executed in a single write cycle or may be timed using edge-triggered or pulsed control signals. In some embodiments, WL1 and WL3 (word lines 108 and 130) may be activated concurrently to maximize write bandwidth, while in other embodiments, staggered activation may be used to mitigate capacitive loading or avoid transient glitches on internal nodes.

In some embodiments, the first word line 108 and the third word line 130 may be asserted with substantially the same signal during a write operation. For example, WL1 and WL3 may both be driven high concurrently during a write cycle to activate a first access transistor 110a, a second access transistor 110a, and a third access transistor 125. This concurrent activation may form a continuous conduction path from the first and second bit lines to the storage nodes Vx and Vy of the cross-coupled inverters 105, facilitating symmetric and time-aligned writing of differential data.

In some embodiments, the first word line 108 and the third word line 130 may be driven with different signals or activated in staggered timing phases. For instance, WL1 may be asserted first to activate the first and second access transistors 110a and 110b, while WL3 may be pulsed slightly later to activate the third access transistor 125. This staggered approach may be used to isolate the dynamic node or delay the propagation of the second bit line signal into the inverter latch, which may improve write margin, reduce signal contention, or limit coupling noise. Such variations in control timing may allow tuning of the bitcell behavior for process-specific or application-specific needs.

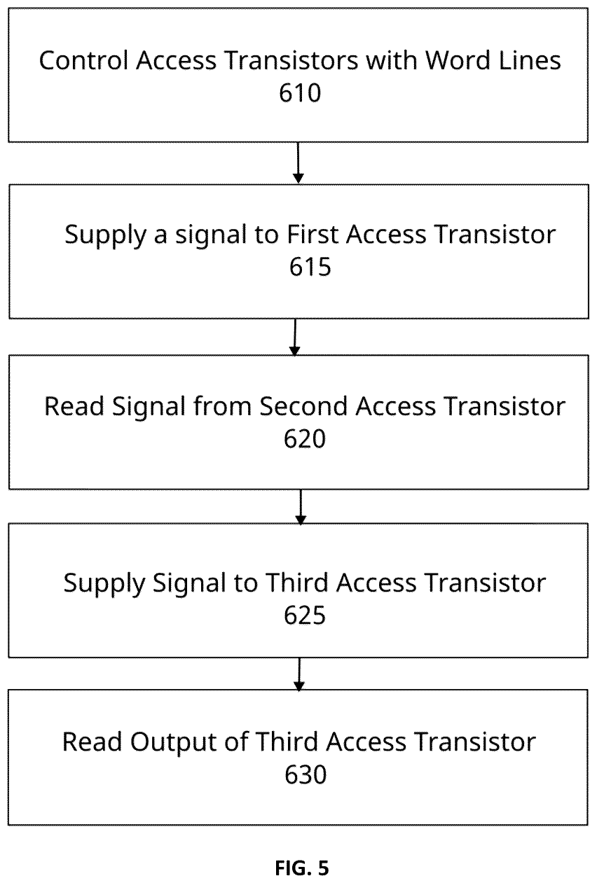

FIG. 5 is a block diagram illustrating an example method for reading a bit value from a memory circuit comprising a 9T SRAM cell (like cell 100), in accordance with one or more embodiments. At step 610, one or more access transistors may be controlled using a first word line. In some embodiments, the first word line may correspond to word line 108, which when asserted activates a first access transistor 110a and a second access transistor 110b. These transistors may allow electrical coupling between the cross-coupled inverter latch and respective bit lines.

At step 615, a signal may be supplied to the first access transistor 110a via the first bit line 115. In some embodiments, this signal may be a precharge voltage which is used to charge the bit line prior to reading. The charge distribution or voltage drop resulting from the connection to the storage node may then be monitored as an indicator of the stored bit.

At step 620, a signal may be read from the second access transistor 110b via the second bit line 120. This signal may reflect the state of the opposing storage node, and its behavior may be influenced by the charge stored on that node and the current path through the enabled access transistor.

At step 625, a third access transistor (e.g., transistor 125) may be controlled by a third word line. This transistor may be interposed between the dynamic node and the second bit line 120, and when activated, it may further propagate the sensed signal or its conditioning through the dynamic node region.

At step 630, the output of the third access transistor may be read back to the second bit line 120 or to a sense amplifier coupled thereto. In some embodiments, this structure may allow the signal to be conditioned, gated, or dynamically influenced before final sensing. For example, the third access transistor 125 may act as a pass-gate or switch to isolate the bit line during certain timing windows or to reduce leakage paths from the storage node. The described read structure may be advantageous in managing read-disturb sensitivity, supporting selective row activation, and accommodating future logic-in-memory extensions.

The read method illustrated in FIG. 5 may be implemented using either static or pulsed word line controls, and the timing relationships between word lines 108 and 130 may vary depending on the desired signal margin, sensing window, or array-level coordination. The approach may support both conventional data retrieval and extended sensing configurations using dynamic control elements within the cell.

In some embodiments, the first word line 108 and the third word line 130 may also be asserted simultaneously or concurrently during read operations to establish a continuous read path from the storage node Vy, through the second and third access transistors 110b and 125, to the second bit line 120. When read speed is prioritized, simultaneous activation of these word lines may reduce signal latency and facilitate direct coupling between the cross-coupled inverter and the sense amplifier. This approach may be effective in high-performance read scenarios where timing resolution is tightly constrained.

In some embodiments, the first word line 108 and the third word line 130 may be controlled independently during read operations. For example, WL1 may be asserted to precharge or enable the initial access path through transistor 110a, while WL3 remains deasserted to temporarily isolate the third access transistor 125. WL3 may then be pulsed after the internal storage node stabilizes, gating the signal to the bit line at a controlled time. This staged read path may improve read robustness by preventing early discharge of the bit line or reducing read disturb effects. Such independent timing schemes may be useful in low-voltage operation, near-threshold computing environments, or in bitcells designed with asymmetric access paths.

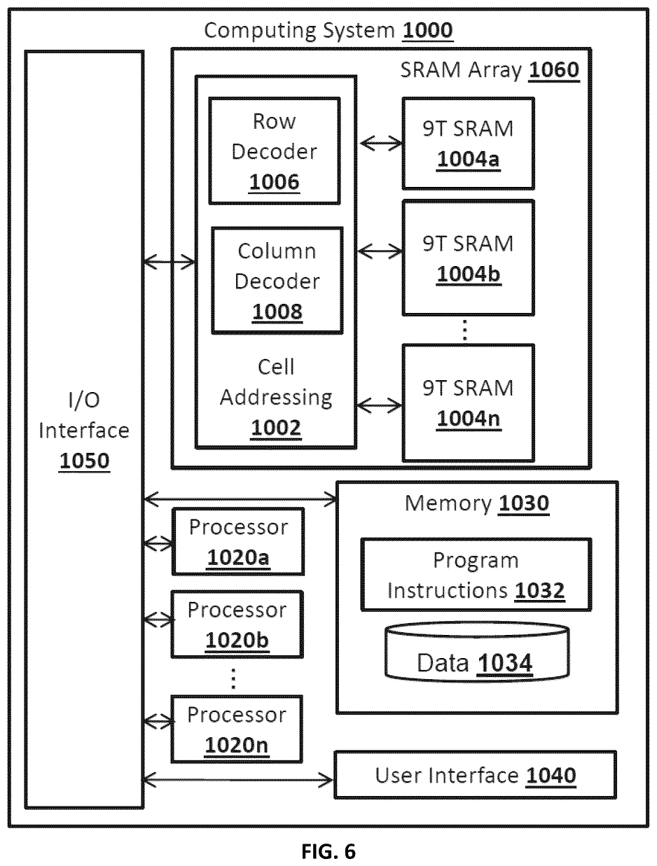

FIG. 6 is a diagram that illustrates an exemplary computing system 1000 in accordance with embodiments of the present technique. System 100 may include memory made with the techniques described above, in the architectures described above, or executing the methods described above. Memory in this system 1000 may be implemented with the techniques above in some cases. Various portions of systems and methods described herein, may include or be executed on one or more computing systems similar to computing system 1000. Further, processes and modules described herein may be executed by one or more processing systems similar to that of computing system 1000.

Computing system 1000 may include one or more processors (e.g., processors 1020a-1020n) coupled to system memory 1030, an SRAM array 1060, and a user interface 1040, through an input/output (I/O) interface 1050. The user interface 1040 may include one or more of an input/output (I/O) device, such as via an input/output (I/O) device interface, and a network, such as via a network interface. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1000. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1030). Computing system 1000 may be a uniprocessor system including one processor (e.g., processor 1020a), or a multi-processor system including any number of suitable processors (e.g., 1020a - 1020n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus can also be implemented as, special purpose logic circuitry, e.g., an FPGA (field programmable gate array) or an ASIC (application specific integrated circuit). Computing system 1000 may include a plurality of computing devices (e.g., distributed computing systems) to implement various processing functions.

The SRAM array 1060 may include one or more elements of cell addressing, such as depicted in cell addressing logic 1002. The cell addressing logic 1002 may include one or more or a word decoder 1006 and a column decoder 1008. The cell addressing logic 1002 may allow for one or more cells of the SRAM array 1060 to be read, written, erased, toggles, etc., including according to instructions from a processor (e.g., processors 1020a-1020n), memory 1030, etc. The SRAM array 1060 may include one or more 9T SRAM cell 1004a-1004n. The 9T SRAM cells 1004a-1004n may be any appropriate 9T SRAM cells, such as previously described. The SRAM array 1060 may include additional memory cells, including additional SRAM cells, which may or may not be arrayed (e.g., not located in row and columns, such as in or other edge architecture) or other volatile or non-volatile memory cells. The SRAM array 1060 may include additional processing architecture, such as amplifiers, analog to digital converters, digital to analog converters, sensors, comparators, etc. The SRAM array 1060 may be in communication with one or more sensors, such as photosensors, photodiodes, etc. The SRAM array 1060 may have any appropriate array architecture.

I/O devices may include devices that receive input (e.g., from a user) or output information (e.g., to a user). I/O devices may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices may be connected to computing system 1000 through a wired or wireless connection. I/O devices may be connected to computing system 1000 from a remote location. I/O devices located on remote computer systems, for example, may be connected to computing system 1000 via a network.

System memory 1030 may be configured to store program instructions 1032 or data 1034. Program instructions 1032 may be executable by a processor (e.g., one or more of processors 1020a-1020n) to implement one or more embodiments of the present techniques. Program instructions 1032 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1030 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard-drives), or the like. System memory 1030 may include a non-transitory computer readable storage medium that may have program instructions stored thereon that are executable by a computer processor (e.g., one or more of processors 1020a-1020n) to cause the subject matter and the functional operations described herein. A memory (e.g., system memory 1030) may include a single memory device and/or a plurality of memory devices (e.g., distributed memory devices). Instructions or other program code to provide the functionality described herein may be stored on a tangible, non-transitory computer readable media. In some cases, the entire set of instructions may be stored concurrently on the media, or in some cases, different parts of the instructions may be stored on the same media at different times.

I/O interface 1050 may be configured to coordinate I/O traffic between processors 1020a-1020n, system memory 1030, network interface, I/O devices, and/or other peripheral devices. I/O interface 1050 may perform protocol, timing, or other data transformations to convert data signals from one component (e.g., system memory 1030) into a format suitable for use by another component (e.g., processors 1020a-1020n). I/O interface 1050 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computer system 1000 or multiple computer systems 1000 configured to host different portions or instances of embodiments. Multiple computer systems 1000 may provide for parallel or sequential processing/execution of one or more portions of the techniques described herein.

Those skilled in the art will appreciate that computer system 1000 is merely illustrative and is not intended to limit the scope of the techniques described herein. Computer system 1000 may include any combination of devices or software that may perform or otherwise provide for the performance of the techniques described herein. For example, computer system 1000 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computer system 1000 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. In some embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computer system 1000 may be transmitted to computer system 1000 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g. within a data center or geographically), or otherwise differently organized. The functionality described herein may be provided by one or more processors of one or more computers executing code stored on a tangible, non-transitory, machine readable medium. In some cases, notwithstanding use of the singular term “medium,” the instructions may be distributed on different storage devices associated with different computing devices, for instance, with each computing device having a different subset of the instructions, an implementation consistent with usage of the singular term “medium” herein. In some cases, third party content delivery networks may host some or all of the information conveyed over networks, in which case, to the extent information (e.g., content) is said to be supplied or otherwise provided, the information may provided by sending instructions to retrieve that information from a content delivery network.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to cost constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques will be better understood with reference to the following enumerated embodiments:

1. A memory circuit comprising: a pair of cross-coupled inverters, the pair of cross-coupled inverters accessible by bit lines, wherein the access of the bit lines to the pair of cross-coupled inverters is controlled by access transistors, the access transistors controlled by a word line; and a dynamic node between one of the access transistors and one of the bit lines, the dynamic node storing a bit value.

2. The memory circuit of embodiment 1, wherein the dynamic node is separated from the one of the bit lines by a secondary access transistor, the secondary access transistor controlled by a secondary word line.

3. The memory circuit of embodiment 1, further comprising a reset line, wherein the reset line is configured to apply a signal between the other of the access transistors and the pair of cross-coupled inverters.

4. The memory circuit of embodiment 3, wherein the reset line comprises a first reset transistor, the first reset transistor controlled by a value of the dynamic node.

5. The memory circuit of embodiment 3, wherein the reset line comprises a second reset transistor, the second reset transistor controlled by a reset word line.

6. The memory circuit of embodiment 3, wherein the reset line is configured to accept a signal from a reset bit line.

7. The memory circuit of embodiment 3, wherein a first reset transistor and a second reset transistor have higher on-current than other transistors of the memory circuit.

8. The memory circuit of embodiment 1, wherein the memory circuit comprises static random-access memory (SRAM).

9. A method of fabricating the memory circuit of any one of embodiments 1 to 8.

10. An array of memory circuits, comprising multiple of the memory circuit any one of embodiments 1 to 8.

11. A method of fabricating the array of embodiment 10.

12. A method comprising: writing a bit value to a memory circuit by controlling one or more access transistor with a first word line and supplying a first signal to a first access transistor with a first bit line and a second signal to a second access transistor with a second bit line, wherein writing the bit value further comprises controlling a third access transistor with a third word line and wherein supplying the second signal to the second access transistor with the second bit line comprises supplying the second signal to the third access transistor with the second bit line and supplying an output of the third access transistor to the second access transistor.

13. The method of embodiment 12, wherein the first signal and the second signal are inverse signals.

14. The method of embodiment 12, wherein the first word line and the third word line supply substantially the same signals.

15. The method of embodiment 12, wherein the first word line and the third word line supply different signals.

16. The method of embodiment 12, wherein writing the bit value comprises steps for an XOR operation.

17. The method of embodiment 12, wherein writing the bit value comprises steps for conditionally flipping the bit value.

18. The method of embodiment 12, wherein writing the bit value comprises steps for setting the bit value to substantially zero.

19. The method of embodiment 12, further comprising: turning on the first access transistor and the second access transistor with the first word line and turning off the third access transistor with the third word line, wherein turning on the first access transistor and the second access transistor with the first word line and turning off the third access transistor with the third word line stores the bit value at a dynamic node between the second access transistor and the third access transistor.

20. The method of embodiment 19, further comprising resetting the bit value by applying a reset signal to a reset transistor controlled by a reset word line, the reset transistor supplying a signal to a node transistor, the node transistor controlled by the bit value of the dynamic node and the node transistor supplying a signal to the first access transistor.

21. The method of embodiment 19, further comprising conditionally flipping the bit value when the bit value of the dynamic node is substantially nonzero by applying a reset signal to a reset transistor controlled by a reset word line, the reset transistor supplying a signal to a node transistor, the node transistor controlled on by the bit value of the dynamic node and the node transistor zeroing a bit value of the first access transistor.

22. A method comprising: reading a bit value of a memory circuit by controlling one or more access transistor with a first word line and supplying a first signal to a first access transistor with a first bit line and reading a second signal from a second access transistor with a second bit line, wherein reading the bit value further comprises controlling a third access transistor with a third word line and wherein reading the second access signal from the second access transistor with the second bit line comprises supplying the second signal to the third access transistor and reading an output of the third access transistor to the second bit line.

23. The method of embodiment 22, wherein the second signal comprises the first signal or an inverse of the first signal.

24. The method of embodiment 22, wherein the first word line and the third word line supply substantially the same signals.

25. The method of embodiment 22, wherein the first word line and the third word line supply different signals.

26. The method of embodiment 22, wherein reading the bit value comprises steps for an XOR operation.

27. The method of embodiment 22, wherein reading the bit value comprises steps for conditionally flipping the bit value.

28. The method of embodiment 22, wherein reading the bit value comprises steps for setting the bit value to substantially zero.

29. The method of embodiment 22, wherein reading the bit value further comprises: turning on the first access transistor and the second access transistor with the first word line and turning off the third access transistor with the third word line; and
reading the bit value from a dynamic node between the second access transistor and the third access transistor.

30. The method of embodiment 29, further comprising resetting the bit value by applying a reset signal to a reset transistor controlled by a reset word line, the reset transistor supplying a signal to a node transistor, the node transistor controlled by the bit value of the dynamic node and the node transistor supplying a signal to the first access transistor.

31. The method of embodiment 29, further comprising conditionally flipping the bit value when the bit value of the dynamic node is substantially nonzero by applying a reset signal to a reset transistor controlled by a reset word line, the reset transistor supplying a signal to a node transistor, the node transistor controlled on by the bit value of the dynamic node and the node transistor zeroing a bit value of the first access transistor.

32. The memory circuit of any one of embodiments 1 to 8, further comprising tangible, non-transitory, machine readable medium storing instructions that when executed cause operations comprising the method of any one of embodiments 22 to 31.

33. A memory circuit comprising: a pair of cross-coupled inverters, the pair of cross-coupled inverters accessible by bit lines; a first transistor and a second transistor, each coupled between a corresponding node of the pair of cross-coupled inverters and a respective bit line, the first and second transistors being coupled to a first word line; a dynamic node electrically coupled between the second transistor and the second bit line, the dynamic node being configured to store a bit value; a third transistor coupled between the dynamic node and a third bit line, the third transistor having a gate coupled to the dynamic node; and a fourth transistor having a gate terminal coupled to a second word line and a conduction path coupled to the third transistor.

34. The memory circuit of embodiment 33, wherein the dynamic node is separated from the one of the bit lines by a fifth transistor, the fifth transistor controlled by a third word line.

35. The memory circuit of embodiment 33, wherein the third bit line is configured to apply a signal between the third and fourth transistors and the pair of cross-coupled inverters.

36. The memory circuit of embodiment 33, wherein the second word line is configured to accept a signal from the third bit line.

37. The memory circuit of embodiment 33, wherein the third transistor and the fourth transistor have higher on-current than other transistors of the memory circuit.

38. The memory circuit of embodiment 33, wherein the memory circuit comprises static random-access memory (SRAM).

39. A method comprising: resetting a bit value in a memory circuit by controlling a first transistor and a second transistor with a first word line and controlling a third transistor with a second word line, wherein controlling the first transistor and the second transistor with the first word line and controlling the third transistor with the second word line stores a bit value at a dynamic node located between the second transistor and the third transistor; and applying a reset signal to a fourth transistor with a third word line, the fourth transistor supplying the reset signal to a fifth transistor, the fifth transistor controlled by the bit value of the dynamic node, and the fifth transistor supplying the reset signal to the first transistor to reset the bit value.

40. The method of embodiment 39, wherein the reset signal comprises a negative voltage signal supplied through the reset line.

41. The method of embodiment 39, wherein the fifth transistor is turned on only when the bit value of the dynamic node is at a logic high voltage.

42. The method of embodiment 39, further comprising steps for erasing data of the memory circuit by applying the reset signal to the third word line.

43. A tangible, non-transitory, machine-readable medium storing instructions that when executed by a data processing apparatus cause the data processing apparatus to perform operations comprising: the operations of any one of embodiments 39-42.

32. The memory circuit of any one of embodiments 33-38, further comprising tangible, non-transitory, machine readable medium storing instructions that when executed cause operations comprising the method of any one of embodiments 39-42.

What is claimed is:

1. A memory circuit comprising:
a pair of cross-coupled inverters, the pair of cross-coupled inverters being accessible by bit lines, wherein access of the bit lines to the pair of cross-coupled inverters is controlled by access transistors, the access transistors being controlled by a word line; and
a dynamic node between one of the access transistors and one of the bit lines, the dynamic node being configured to store a bit value.

2. The memory circuit of claim 1, wherein the dynamic node is separated from the one of the bit lines by a secondary access transistor, the secondary access transistor being controlled by a secondary word line.

3. The memory circuit of claim 1, further comprising a reset line, wherein the reset line is configured to apply a signal between the other of the access transistors and the pair of cross-coupled inverters.

4. The memory circuit of claim 3, wherein the reset line comprises a first reset transistor, the first reset transistor being controlled by a value of the dynamic node.

5. The memory circuit of claim 3, wherein the reset line comprises a second reset transistor, the second reset transistor being controlled by a reset word line.

6. The memory circuit of claim 3, wherein the reset line is configured to accept a signal from a reset bit line.

7. The memory circuit of claim 3, wherein a first reset transistor and a second reset transistor have higher on-current than other transistors of the memory circuit.

8. The memory circuit of claim 1, wherein the memory circuit comprises static random-access memory (SRAM).

9. A method comprising:
writing a bit value to a memory circuit by controlling one or more access transistors with a first word line and supplying a first signal to a first access transistor with a first bit line and a second signal to a second access transistor with a second bit line,
wherein writing the bit value further comprises controlling a third access transistor with a third word line and wherein supplying the second signal to the second access transistor with the second bit line comprises supplying the second signal to the third access transistor with the second bit line and supplying an output of the third access transistor to the second access transistor.

10. The method of claim 9, wherein the first signal and the second signal are inverse signals.

11. The method of claim 9, wherein the first word line and the third word line supply substantially the same signals.

12. The method of claim 9, wherein:
the first word line and the third word line supply different signals;
writing the bit value comprises steps for an XOR operation;
writing the bit value comprises steps for conditionally flipping the bit value; or
writing the bit value comprises steps for setting the bit value to substantially zero.

13. The method of claim 9, further comprising turning on the first access transistor and the second access transistor with the first word line and turning off the third access transistor with the third word line, wherein turning on the first access transistor and the second access transistor with the first word line and turning off the third access transistor with the third word line stores the bit value at a dynamic node between the second access transistor and the third access transistor.

14. The method of claim 13, further comprising resetting the bit value by applying a reset signal to a reset transistor controlled by a reset word line, the reset transistor supplying a signal to a node transistor, the node transistor controlled by the bit value of the dynamic node and the node transistor supplying a signal to the first access transistor.

15. The method of claim 13, further comprising conditionally flipping the bit value when the bit value of the dynamic node is substantially nonzero by applying a reset signal to a reset transistor controlled by a reset word line, the reset transistor supplying a signal to a node transistor, the node transistor controlled on by the bit value of the dynamic node and the node transistor zeroing a bit value of the first access transistor.

16. A method comprising:
reading a bit value of a memory circuit by controlling one or more access transistors with a first word line and supplying a first signal to a first access transistor with a first bit line and reading a second signal from a second access transistor with a second bit line,
wherein reading the bit value further comprises controlling a third access transistor with a third word line and wherein reading the second access signal from the second access transistor with the second bit line comprises supplying the second signal to the third access transistor and reading an output of the third access transistor to the second bit line.

17. The method of claim 16, wherein:
the second signal comprises the first signal or an inverse of the first signal; or
the first word line and the third word line supply substantially the same signals.

18. The method of claim 16, wherein:
the first word line and the third word line supply different signals; and
reading the bit value comprises steps for an XOR operation.

19. The method of claim 16, wherein reading the bit value comprises steps for conditionally flipping the bit value.

20. The method of claim 16, wherein reading the bit value further comprises:
turning on the first access transistor and the second access transistor with the first word line and turning off the third access transistor with the third word line; and
reading the bit value from a dynamic node between the second access transistor and the third access transistor,
the method further comprising:
resetting the bit value by applying a reset signal to a reset transistor controlled by a reset word line, the reset transistor supplying a signal to a node transistor, the node transistor controlled by the bit value of the dynamic node and the node transistor supplying a signal to the first access transistor; or
conditionally flipping the bit value when the bit value of the dynamic node is substantially nonzero by applying a reset signal to a reset transistor controlled by a reset word line, the reset transistor supplying a signal to a node transistor, the node transistor controlled on by the bit value of the dynamic node and the node transistor zeroing a bit value of the first access transistor.
